(19) United States
(12) Patent Application Publication
(10) Pub. No.: US 2006/0255421 A1
(43) Pub. Date: Nov. 16, 2006

(54) Photo detecting element for monitoring optical power and optical pick up apparatus thereof

(75) Inventors: Jong-Uk Kim, Yongin-si (KR); Young-Sun Jeon, Seoul (KR); Bong-Gi Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/429,978

(22) Filed: May 9, 2006

(30) Foreign Application Priority Data
May 11, 2005 (KR) 2005-0039279

(51) Int. Cl. H01L 31/00

(52) U.S. Cl. 257/458

(57) ABSTRACT

A photo detecting element for monitoring optical power and optical pick up apparatus using the same are provided. The photo detecting element for monitoring optical power has an optical detecting element connected to first and second sensitivity controllers for controlling sensitivity of an optical power signal with respect to the optical power monitored using one of the first and second sensitivity controllers. The photo detecting element also has a third sensitivity controller connected to the optical detecting element for monitoring optical power, and a switching part to enable selective use of the third sensitivity controller for control of the optical power signal instead of the second sensitivity controller according to an external switching control signal. Accordingly, optical power equal to or exceeding three lights can be monitored using an optical detecting element having the monitoring capability of monitoring the optical power of two lights.

### PRIORITY

This application claims the benefit under 35 U.S.C. § 119(a) of Korean patent application No. 2005-39279, filed May 11, 2005, in the Korean Intellectual Property Office, the entire contents of which are hereby incorporated by reference.

### BACKGROUND OF THE INVENTION

1. Field of the Invention

The present invention relates to a photo detecting element for monitoring optical power and an optical pick up apparatus thereof. More particularly, the present invention relates to a photo detecting element for monitoring optical power and an optical pick up apparatus thereof capable of monitoring an optical power equal to or exceeding three lights using a photo detecting element for monitoring optical power that is able to monitor the optical power of two lights.

2. Description of the Related Art

A photo detecting element for monitoring optical power consists of an optical pick up apparatus reading data recorded on an optical disc and generating an electric signal corresponding to the data read.

An optical pick up apparatus detects intensity of light reflected by an optical disc and projected from a light source in order to read data recorded on the optical disc. The photo detecting element provided at the optical pick up monitors the optical power of light projected from a light source, so that the optical power of light projected from the light source can be maintained at a proper level.

FIG. 1 is a circuit diagram of a photo detecting element for monitoring optical power and is configured by electrically connecting R₁, R₂, C₁ and C₂ to a monitor photo diode (MPD) IC driven by ‘VCC’ power. C₁ and C₂ are connected for bypass.

The MPD IC is a photo detecting element for monitoring optical power made of a single chip, such that the optical power of two lights (for example, one light for CD reproduction and the other light for DVD reproduction) is monitored. In particular, the MPD IC monitors the optical power of light projected from a light source (not shown) and creates an electric signal corresponding to the monitored optical power (hereinafter abbreviated ‘optical power signal’), to output through ‘Vout’ 17. The optical power signal output from the MPD IC is used for maintaining the optical power at a proper level.

R₁ comprises a sensitivity controller for controlling the sensitivity of an optical power signal with respect to the optical power of light for CD reproduction (hereinafter abbreviated ‘CD optical power’). R₂ comprises a sensitivity controller used for controlling the sensitivity of an optical power signal with respect to the optical power of light for DVD reproduction (hereinafter abbreviated ‘DVD optical power’).

The MPD IC controls the sensitivity of an optical power signal through use of R₁ and R₂. The sensitivity controller used by MPD IC to control sensitivity of the optical power signal is determined according to a selection signal input through port ‘SW’ 15.

In particular, when the selection signal has a ‘High’ logic level, the MPD IC uses R₁ connected across ports ‘Vin1’ 14 and ‘IVout’ 11. On the other hand, when the selection signal is at a ‘Low’ logic level, the MPD IC uses R₂ connected across ports ‘Vin2’ 13 and ‘IVout’ 11.

As shown in FIG. 1, the photo detecting element for monitoring optical power using an MPD IC capable of monitoring the optical power of two lights only.

In accordance with current technology of optical discs, such as Blue-ray Disk (BD) (also known as Blu-ray Disc), an optical pick up apparatus should be designed to be capable of reading three optical discs. This capability could be realized by developing an MPD IC capable of monitoring the optical power of three lights. However, such a capability would require significant time and effort to develop an MPD IC capable of monitoring the optical power of three lights, and the use of such an MPD IC would require significant design changes in the remaining circuit structure of the optical pick up apparatus.

### SUMMARY OF THE INVENTION

Accordingly, an aspect of exemplary embodiments of the present invention is to solve at least the above identified problems and/or disadvantages and to provide at least the advantages described below. Thus, an aspect of exemplary embodiments of the present invention provide a photo detecting element for monitoring optical power and an optical pick up apparatus thereof capable of monitoring optical power equal to or exceeding three lights using an optical detecting element capable of monitoring the optical power of two lights.

In order to achieve the above-described aspects of exemplary embodiments of the present invention, a photo detecting element for monitoring optical power is provided that comprises an optical detecting element connected to first and second sensitivity controllers and controlling sensitivity of an optical power signal with respect to optical power monitored using one of the first and second sensitivity controllers. The photo detecting element further comprises a third sensitivity controller connected to the optical detecting element for monitoring optical power, and a switching part to enable selective use of the third sensitivity controller for control of the optical power signal instead of the second sensitivity controller according to an external switching control signal.

In exemplary embodiments, one end of the second sensitivity controller and one end of the third sensitivity controller are connected to a first port of the optical detecting element, while the switching part is connected to a second end of the second sensitivity controller, a second end of the third sensitivity controller, and a second port of the optical detecting element.

In exemplary embodiments the switching part can be operated according to an external switching control signal to electrically connect the second end of the second sensitivity controller and the second port of the optical detecting element, or to electrically connect the second end of the third sensitivity controller and the second port of the optical detecting element.

In exemplary embodiments the photo detecting element for monitoring optical power further comprises a fourth sensitivity controller connected to the optical detecting element, and another switching part such that the fourth sensitivity controller is able to selectively control sensitivity of the optical power signal according to another external switching control signal, instead of the first sensitivity controller, when the selected signal controls sensitivity of the optical power by use of the first sensitivity controller.

The third sensitivity controller may be used for controlling sensitivity of the optical power signal with respect to at least one of an optical power of light for CD reproduction, an optical power of light for DVD reproduction, an optical power of light for BD reproduction, an optical power of light for CD recording, an optical power of light for DVD recording, and an optical power of light for BD recording.

The optical detecting element for monitoring optical power in accordance with the present invention comprises a single chip.

According to an exemplary embodiment of the present invention, an optical pick up apparatus for reading data recorded to an optical disc and creating an electric signal corresponding to the data read, comprises an optical detecting element connected to first and second sensitivity controllers and controlling sensitivity of an optical power signal with respect to optical power monitored using one of the first and second sensitivity controllers according to input from a selection signal. The optical pick up apparatus further comprises a third sensitivity controller connected to the optical detecting element for monitoring optical power, and a switching part to enable selective use of the third sensitivity controller for control of the optical power signal instead of the second sensitivity controller according to an external switching control signal.

In exemplary embodiments, one end of the second sensitivity controller and one end of the third sensitivity controller are connected to a first port of the optical detecting element for monitoring optical power, while the switching part is connected to a second end of the second sensitivity controller, a second end of the third sensitivity controller, and a second port of the optical detecting element.

In exemplary embodiments, the switching part can be operated according to an external switching control signal to electrically connect the second end of the second sensitivity controller and the second port of the optical detecting element, or to electrically connect the second end of the third sensitivity controller and the second port of the optical detecting element.

According to an exemplary embodiment of the present invention, an optical reproduction apparatus for reproducing data recorded to an optical disc comprises an optical detecting element connected to first and second sensitivity controllers and controlling sensitivity of an optical power signal with respect to optical power monitored using one of the first and second sensitivity controllers. The optical reproduction apparatus further comprises a third sensitivity controller connected to the optical detecting element for monitoring optical power, and a switching part to enable selective use of the third sensitivity controller for control of the optical power signal instead of the second sensitivity controller according to an external switching control signal.

### BRIEF DESCRIPTION OF THE DRAWING FIGURES

The above aspects, exemplary features and advantages of the present invention will become more apparent from the following detailed description of certain exemplary embodiments thereof when taken in conjunction with the accompanying drawing figures, in which:

FIG. 1 is a circuit diagram of a conventional photo detecting apparatus for monitoring;

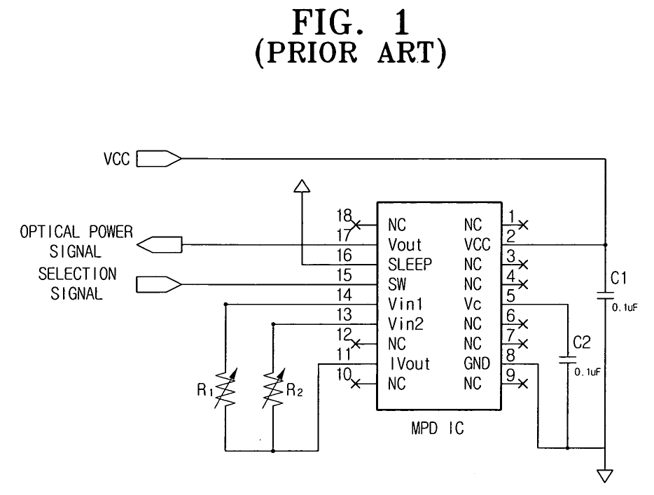

FIG. 2 is a block diagram of a photo detecting apparatus for monitoring according to an exemplary embodiment of the present invention; and

FIG. 3 is a circuit diagram of a photo detecting apparatus for monitoring according to an exemplary embodiment of FIG. 2.

Throughout the drawings, like reference numbers should be understood to refer to like elements, features, and structures.

### DETAILED DESCRIPTION OF EXEMPLARY EMBODIMENTS

The matters exemplified in this description are provided to assist in a comprehensive understanding of various exemplary embodiments of the present invention disclosed with reference to the accompanying figures. Accordingly, those of ordinary skill in the art will recognize that various changes and modifications of the exemplary embodiments described herein can be made without departing from the scope and spirit of the claimed invention. Descriptions of well-known functions and constructions are omitted for clarity and conciseness.

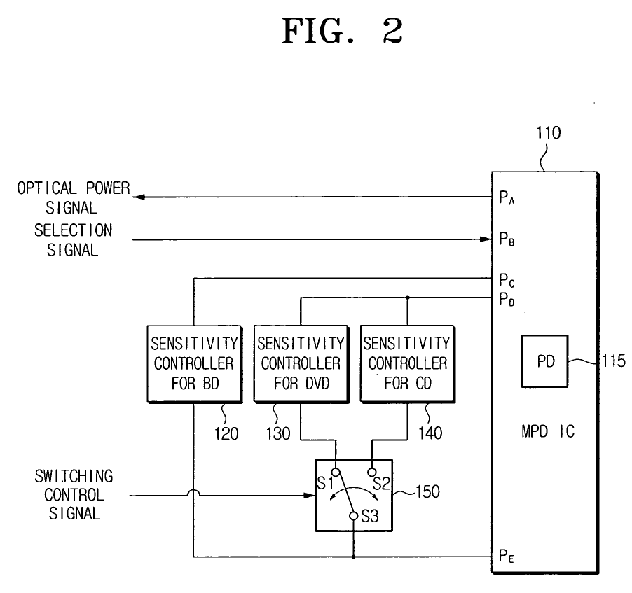

FIG. 2 is a block diagram of a photo detecting element for monitoring optical power according to an exemplary embodiment of the present invention. The photo detecting element for monitoring is capable of monitoring at an optical power equal to or exceeding three lights while using a photo detecting element that is capable of monitoring the optical power of two lights.

As shown in FIG. 2, a photo detecting element in accordance with an exemplary embodiment of the present invention comprises a Monitor Photo Diode (MPD) IC 110, a sensitivity controller 120 for Blue-ray Disk (BD), a sensitivity controller for Digital Video Disk (DVD) 130, a sensitivity controller for Compact Disk (CD) 140, and a switching part 150.

MPD IC is an optical detecting element for monitoring comprising a single chip to monitor the optical power of two lights. In particular, MPD IC 110 monitors the optical power of light projected to Photo Diode (PD) 115 after projection from a light source (not shown), and creates an optical power signal to output through port P_{A}. The optical power signal output from MPD IC 110 is used for maintaining constant optical power at a proper level.

MPD IC 110 uses at least one of a sensitivity controller for BD 120, a sensitivity controller for DVD 130, and a sensitivity controller for CD 140, to control sensitivity of the optical power signal.

A sensitivity controller used by MPD IC 110 for controlling sensitivity of the optical power signal is controlled by a selection signal input through port P_{B}.

In particular, in the case of a selection signal having a ‘High’ logic level, MPD IC 110 uses the sensitivity controller for BD 120 connected across port P_{C} and port P_{E}. On the other hand, in the case of a selection signal having a ‘Low’ logic level, MPD IC 110 uses the sensitivity controller for DVD 130 or the sensitivity controller for CD 140 connected to across port P_{D} and port P_{E}, depending on the position of switching part 150.

The sensitivity controller for BD 120 is used for controlling sensitivity of an optical power signal with respect to the optical power of light for BD reproduction. One end of the sensitivity controller for BD 120 is connected to port P_{C} of MPD IC 110, and the other end is connected to port P_{E}.

The sensitivity controller for DVD 130 is used to control sensitivity of an optical power signal with respect to the optical power of light for DVD reproduction. One end of the sensitivity controller for DVD 130 is connected to port P_{D} of MPD IC 110, and the other end is connected to switching part 150, which is described later.

The sensitivity controller for CD 140 is used to control sensitivity of an optical power signal with respect to the optical power of light for CD reproduction. One end of the sensitivity controller for CD 140 is connected to port P_{D} of MPD IC 110, and the other end is connected to switching part 150.

The sensitivity controller for BD 120, the sensitivity controller for DVD 130, and the sensitivity controller for CD 140 can be embodied with variable resistance elements wherein each resistance value may vary during manufacturing processes.

The switching part 150 is connected to sensitivity controller for DVD 130, sensitivity controller for CD 140, and port P_{E} of MPD IC 110. In particular, the sensitivity controller for DVD 130 is connected to terminal S₁ of switching part 150, the sensitivity controller for CD 140 is connected to terminal S₂ of switching part 150, and port P_{E} of MPD IC 110 is connected to terminal S₃ of switching part 150.

The switching part 150 is operated by a switching control signal. In particular, if the switching control signal is at a ‘High’ logic level, the switching part 150 is operated to electrically connect terminal S₁ and terminal S₃, such that the sensitivity controller for DVD 130 is electrically connected between port P_{D} and Port P_{E} of MPD IC 110. On the other hand, if the switching control signal is at a ‘Low’ logic level, the switching part 150 is operated to electrically connect terminal S₂ and terminal S₃, such that the sensitivity controller for CD 140 is electrically connected between port P_{D} and Port P_{E} of MPD IC 110.

An operational process of an exemplary embodiment of the photo detecting element for monitoring optical power will be described in detail. The photo detecting element for monitoring optical power in accordance with an exemplary embodiment of the present invention can monitor the optical power of three lights. The optical power of three lights comprises: i) the optical power of light for BD reproduction (hereinafter abbreviated as ‘BD optical power’); ii) the optical power of light for DVD reproduction (hereinafter abbreviated as ‘DVD optical power’); and iii) the optical power of light for CD reproduction (hereinafter abbreviated as ‘CD optical power’).

When reading data recorded for BD, that is, the light for BD reproduction is projected by a light source and MPD IC 110 monitors BD optical power, the selection signal is at a ‘High’ logic level. Accordingly, the MPD IC 110 uses the sensitivity controller for BD 120 connected to port P_{C} and port P_{E} to control the sensitivity of the optical power signal with respect to BD optical power.

When reading data recorded for DVD, that is, the light for DVD reproduction is projected by a light source and MPD IC 110 monitors DVD optical power, the selection signal is at a ‘Low’ logic level and the switching control signal is at a ‘High’ logic level. Since the logic level of the selection signal is ‘Low,’ MPD IC 110 uses the sensitivity controller connected to port P_{D} and port P_{E}. Since the switching control signal has a ‘High’ logic level, the switching part 150 is operated to electrically connect terminal S₁ and terminal S₃, such that the sensitivity controller for DVD 130 is connected between port P_{D} and port P_{E} of MPD IC 110. As a result, MPD IC 110 uses the sensitivity controller for DVD 130 to control the sensitivity of the optical power signal with respect to DVD optical power.

When reading data recorded for CD, that is, the light for CD reproduction is projected by a light source and MPD IC 110 monitors CD optical power, the selection signal is at a ‘Low’ logic level and the switching control signal is at a ‘Low’ logic level. Since the logic level of the selection signal is ‘Low,’ MPD IC 110 uses the sensitivity controller connected to port P_{D} and port P_{E}. Since the switching control signal has a ‘Low’ logic level, the switching part 150 is operated to electrically connect the terminal S₂ and the terminal S₃, such that the sensitivity controller for CD 140 is connected between port P_{D} and port P_{E} of MPD IC 110. As a result, MPD IC 110 uses the sensitivity controller for CD 140, to control the sensitivity of the optical power signal with respect to CD optical power.

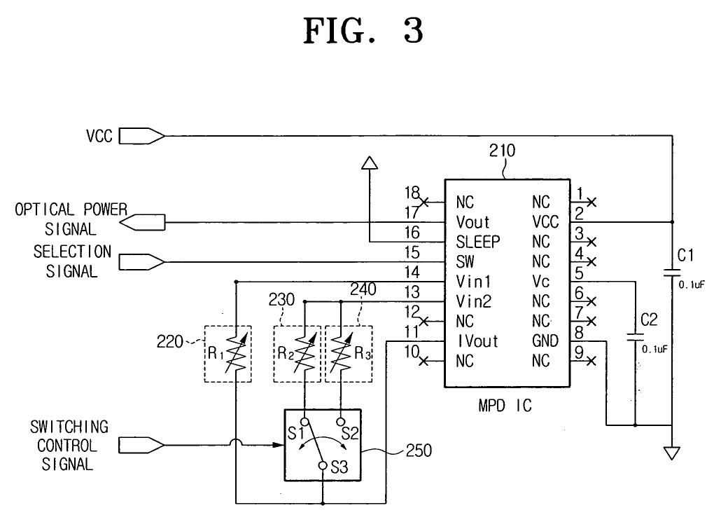

FIG. 3 is a circuit diagram of the photo detecting element for monitoring optical power according to the exemplary embodiment of FIG. 2.

Driven by ‘Vcc’ power, the photo detecting element in FIG. 3 outputs an optical power signal through port ‘Vout’ 17 and provides selection signal input to MPD IC 210 through port ‘SW’ 15. MPD IC 210 port ‘Vcc’ 2 and port ‘Vc’ 5 are coupled to ‘C1’ and ‘C2,’ respectively, which can be, for example, 0.1 μF.

The sensitivity controller for BD 220, the sensitivity controller for DVD 230, and the sensitivity controller for CD 240 comprise ‘R1,’ ‘R2,’ and ‘R3,’ which are a variable resistance elements, respectively.

The switching part 250 may comprise, for example, a switching circuit using a transistor element.

Thus far, the concept of a photo detecting element capable of monitoring the optical power of three lights using an optical detecting element for monitoring optical power capable of monitoring the optical power of two lights has been described in reference to a circuit structure.

According to an exemplary embodiment of the present invention, three lights for monitoring comprise ‘a light for BD reproduction,’ ‘a light for DVD reproduction,’ and ‘a light for CD reproduction,’ for example, but not limited only to this scope as the technical spirit of the present invention may be applied to monitor other kinds of lights as well.

Based on the description above, a photo detecting element capable of monitoring the optical power of lights “equal to or exceeding four lights”, using the optical detecting element for monitoring the optical power of two lights is also contemplated.

For example, a structure between port P_{C} and port P_{E} of MPD IC 110 is configured in the same manner as port P_{D} and port P_{E} using a pair of two sensitivity controllers and a switching part, thus the optical power of four lights can be monitored.

Exemplary embodiments of the present invention read data recorded to optical disc, create an electric signal corresponding to the data read, and are applied to the optical pick up apparatus employing the photo detecting element. In addition, exemplary embodiments of the present invention are also applicable to the optical reproducing apparatus, wherein the above optical pick-up apparatus is employed to reproduce data recorded to an optical disc.

According to exemplary embodiments of the present invention, optical power equal to or exceeding three lights are monitored using an optical detecting element capable of monitoring the optical power of two lights. Accordingly, the time and effort required to develop an MPD IC capable of monitoring optical power equal to or exceeding three lights can be saved. Additionally, the time and effort for designing any optical pick up apparatus using the MPD IC can also be saved and thus limit hindrance to development.

While the present invention has been particularly shown and described with reference to certain exemplary embodiments thereof, it will be understood by those of ordinary skill in the art that various changes in form and detail may be made therein without departing from the spirit and scope of the present invention as defined by the appended claims and equivalents thereof.

What is claimed is:

1. A photo detecting element comprising:
an optical detecting element for monitoring optical power connected to first and second sensitivity controllers and controlling sensitivity of an optical power signal with respect to optical power monitored using one of the first and second sensitivity controllers;
a third sensitivity controller connected to the optical detecting element; and
a switching part to enable selective use of the third sensitivity controller for control of the optical power signal instead of the second sensitivity controller according to an external switching control signal.

2. The photo detecting element as claimed in claim 1, wherein one end of the second sensitivity controller and one end of the third sensitivity controller are connected to a first port of the optical detecting element, while the switching part is connected to a second end of the second sensitivity controller, a second end of the third sensitivity controller, and a second port of the optical detecting element.

3. The photo detecting element as claimed in claim 2, wherein the switching part can be operated according to the external switching control signal to electrically connect the second end of the second sensitivity controller and the second port of the optical detecting element.

4. The photo detecting element as claimed in claim 2, wherein the switching part can be operated according to an external switching control signal to electrically connect the second end of the third sensitivity controller and the second port of the optical detecting element.

5. The photo detecting element as claimed in claim 1, further comprising:
a fourth sensitivity controller connected to the optical detecting element; and
a second switching part for switching such that the fourth sensitivity controller is able to selectively control sensitivity of the optical power signal, according to a second external switching control signal, instead of the first sensitivity controller when the selected signal controls sensitivity of the optical power by use of the first sensitivity controller.

6. The photo detecting element as claimed in claim 1, wherein the third sensitivity controller is used for controlling sensitivity of the optical power signal with respect to at least one of an optical power of light for CD reproduction, an optical power of light for DVD reproduction, an optical power of light for BD reproduction, an optical power of light for CD recording, an optical power of light for DVD recording, and an optical power of light for BD recording.

7. The photo detecting element as claimed in claim 1, wherein the optical detecting element for monitoring optical power comprises a single chip.

8. An optical pick-up apparatus for reading data recorded to an optical disc and creating an electric signal corresponding to data read, the optical pick-up apparatus comprising:
an optical detecting element for monitoring optical power connected to first and second sensitivity controllers and controlling sensitivity of an optical power signal with respect to optical power monitored using one of the first and second sensitivity controllers according to an input selection signal;
a third sensitivity controller connected to the optical detecting element; and
a switching part to enable selective use of the third sensitivity controller for control of the optical power signal instead of the second sensitivity controller according to an external switching control signal.

9. The optical pick-up apparatus as claimed in claim 8, wherein one end of the second sensitivity controller and one end of the third sensitivity controller are connected to a first port of the optical detecting element, while the switching part is connected to a second end of the second sensitivity controller, a second end of the third sensitivity controller, and a second port of the optical detecting element.

10. The optical pick-up apparatus as claimed in claim 9, wherein switching part can be operated according to the external switching control signal to electrically connect the second end of the second sensitivity controller and the second port of the optical detecting element.

11. The optical pick-up apparatus as claimed in claim 9, wherein switching part can be operated according to the external switching control signal to electrically connect the second end of the third sensitivity controller and the second part of the optical detecting element for monitoring.

12. An optical reproduction apparatus for reproducing data recorded to an optical disc, the optical reproduction apparatus comprising:
an optical detecting element connected to first and second sensitivity controllers and controlling sensitivity of an optical power signal with respect to optical power monitored using one of the first and second sensitivity controllers;
a third sensitivity controller connected to the optical detecting element; and
a switching part to enable selective use of the third sensitivity controller for control of the optical power signal instead of the second sensitivity controller according to an external switching control signal.
